(19) United States
(12) Patent Application Publication
(10) Pub. No.: US 2011/0019160 A1
(43) Pub. Date: Jan. 27, 2011

(54) IMAGE DISPLAY APPARATUS

(75) Inventors: Hiroshi Kitano, Osaka (JP); Takayuki Kimoto, Osaka (JP)

Correspondence Address: HAMRE, SCHUMANN, MUELLER & LARSON P.C., P.O. BOX 2902, MINNEAPOLIS, MN, 55402-0902, US

(73) Assignee: Panasonic Corporation, Osaka (JP)

(21) Appl. No.: 12/843,459

(22) Filed: Jul. 26, 2010

(30) Foreign Application Priority Data
Jul. 27, 2009 (JP) 2009-174060

(51) Int. Cl. G03B 21/16; H05K 7/20

(52) U.S. Cl. 353/57; 361/688; 361/691

(57) ABSTRACT

An image display apparatus includes: an image display unit for forming an optical image; and an outer housing for housing the image display unit. The outer housing includes a window for displaying the optical image to the outside. The image display apparatus includes, in the outer housing, a heat insulator placed so as to surround the image display unit and a cooling device for cooling inside the outer housing, and the cooling device has a variable cooling capacity. The image display apparatus is abatable to changes in the ambient temperature and the internal power consumption and the presence or absence of sunlight and can be installed in a variety of outdoor environment, so that a high degree of reliability can be achieved.

### BACKGROUND OF INVENTION

1. Field of the Invention

The present invention relates to image display apparatuses and in particular to an image display apparatus that is used especially in environments with outdoor daylight and illumination such as in the outdoors.

2. Description of Related Art

With an increase in the size, brightness and resolution of image display apparatuses together with the proliferation of network environments, electronic advertising using a video medium has been growing rapidly in recent years. Posters need replacing every time the advertising content requires changing. With electronic advertising, in contrast, the advertising content can be changed instantly by simply changing the contents of the distribution server. Thus, electronic advertising can serve as a useful advertising medium.

Although so-called digital signage such as electronic advertising has been primarily introduced for indoor use, outdoor video display has been gaining attention as a new market. For example, outdoor-specific uses, such as installing a large image display apparatus in an outdoor public space for an unspecified number of viewers for use in sales promotion or advertising or for providing information on public transportation, can be considered.

Direct-view-type displays such as a liquid crystal display and a plasma display have become widely available in recent years as display apparatuses with a large screen. However, these apparatuses have been developed primarily for indoor use and are not suited for outdoor use in their natural state in most instances. This is because there are significant problems, namely viewability and weatherproofness, to the use of these displays in the outdoors.

Especially in a clear-sky environment where direct sunlight is present, an extremely bright display image is essential to ensure sufficient viewability of a video medium. Further, it is also important to display a large and high-resolution image to provide information effectively. High-resolution and relatively-large screens can be attained using liquid crystal displays and plasma displays because their panel size has been upsized in recent years. However, the brightness is insufficient for outdoor use. In principle, it is possible to increase the brightness by increasing the light source power but this requires a significant amount of power consumption. Besides, since the heat load increases in the interior of the display, the reliability deteriorates.

Next, with regard to weatherproofness, it is necessary to give sufficient consideration to severe temperature changes, a temperature increase and ultraviolet exposure by direct sunlight and influences of dust and wind and rain. In direct sunlight under the hot sun, the temperature inside a display housing rises significantly as compared with the outside air temperature, which is likely to result in deterioration and malfunction of the display apparatus. Moreover, for direct-view-type displays, when their panel portion is exposed to direct sunlight, the temperature of display components disposed adjacent to each other in the panel increases and thereby the performance may deteriorate. Conversely, in a freezing environment, liquid crystal displays are unable to display a desired image because the operating characteristic of liquid crystal deteriorates in most instances.

Further, for indoor-use display apparatuses, no measure against precipitation is taken. Also in terms of an amount of dust, the outdoor environment is more adverse than the indoor environment in many cases. That is, because ordinary image display apparatuses are produced to be used in a properly air-conditioned environment, they are not adaptable to severe temperature changes in the outdoors.

Meanwhile, as a weatherproof image display apparatus compatible with outdoor use and capable of providing images with high brightness, a display apparatus using LEDs has been commercialized. However, due to its rough pixel pitch, the screen size needs to be increased relatively in order to achieve high resolution, resulting in a high-cost product with an extremely large amount of power consumption.

On the other hand, as a method utilizing a projector, two systems are available: a rear projector that projects an image onto a transmissive screen via a mirror; and a front projector that projects an image onto a direct reflective screen. By properly adjusting the projection magnification, it is possible to achieve high brightness sufficient for outdoor use.

Also in terms of weatherproofness, the method utilizing a projector can reduce the influence of direct sunlight as compared with direct-view-type displays because the projection unit is placed apart from the screen.

However, not only does the projector include the light source that generates heat but also the projector uses optical devices that are susceptible to performance deterioration caused by an increase in the temperature of image display elements, such as a DMD (Digital Micromirror Device) or a liquid crystal display element, and a polarizing filter. Thus, it is important to cool the housing interior in an efficient manner. Especially, in an outdoor environment where the projector is exposed to direct sunlight, an increase in the temperature of the housing caused by direct sunlight can be a problem. For this reason, it is essential to control the temperature of the projector with consideration given to its usage environment.

Conventionally, as a display apparatus for outdoor installation, for example, JP 2002-311508 A, JP 2002-341810 A and JP 2003-149739 A each disclose a method of placing an air conditioner in a projector housing.

Further, as a technique of cooling a projection type display apparatus in an efficient manner, for example, JP 2000-298311 A, JP 2005-148624A and JP 2001-209125 A each disclose a method of enhancing a cooling effect by using an air conditioner, a heat exchanger, a heat insulator, a partition board, etc.

However, with the conventionally disclosed techniques of enhancing a cooling effect for an image display apparatus, outdoor installation measures may not be sufficient. JP 2002-311508 A, JP 2002-341810 A and JP 2003-149739 A do not define a specific system structure that properly makes full use of the performance of the air conditioner. Although JP 2000-298311 A, JP 2005-148624 A and JP 2001-209125 A disclose a cooling system structure for image display elements and their periphery, they do not consider optimizing a cooling system structure for the overall housing.

To use an image display apparatus for an extended period with a high degree of reliability particularly in the outdoors, detailed studies on environments in which the overall housing is installed are essential, and a high degree of weatherproofness against a temperature and conditions of solar irradiation is required.

Moreover, since the temperature of an image display apparatus changes sharply due to the ambient temperature and the presence and absence of sunlight in an outdoor environment, preferred cooling characteristics change significantly. The cooling capacity demanded of the cooling device increases as the ambient temperature becomes higher, and is larger when the image display apparatus is exposed to direct sunlight than when there is no sunlight. Further, since the preferred brightness of an image display apparatus changes between the daytime and the nighttime, the power consumption of the image display unit varies. In other words, the required cooling capacity changes between the daytime and the nighttime.

### SUMMARY OF THE INVENTION

With the foregoing in mind, it is an object of the present invention to provide an image display apparatus with high resolution and high brightness, while being adaptive to a variety of outdoor environments.

To achieve the above-described object, the image display apparatus of the present invention includes: an image display unit for forming an optical image; and an outer housing for housing the image display unit. The outer housing includes a window for displaying the optical image to the outside. The image display apparatus includes, in the outer housing, a heat insulator placed so as to surround the image display unit and a cooling device for cooling inside the outer housing, and the cooling device has a variable cooling capacity

According to this configuration, by adopting the housing structure and the cooling device that can enhance a cooling effect for the equipped image display unit, the weatherproofness of the image display apparatus can be enhanced properly and effectively. In the outdoors, a variety of usage environments can be considered as compared with indoor use. When a cooling device with a large cooling capacity is operated in every environment, the temperature inside the image display apparatus drops excessively, and a portion where the temperature inside of the image display apparatus is lower than the ambient temperature is formed. Condensation may occur at that portion.

Thus, by making the cooling capacity of the cooling device variable as in the above configuration, it is possible to make the apparatus adaptable to changes in the ambient temperature, the internal power consumption and the presence and absence of sunlight. As a result, it is possible to provide an image display apparatus with a high degree of reliability that can be installed in a variety of outdoor environments as an outdoor display apparatus.

### BRIEF DESCRIPTION OF THE DRAWINGS

FIG. 1 is a cross-sectional view showing a layout of major components of an image display apparatus according to Embodiment 1 of the present invention.

FIG. 2A to 2C are graphs each schematically showing a relationship between a cooling capacity of a cooling device of the image display apparatus and changes in temperature.

FIG. 3 is a cross-sectional view showing a layout of major components of an image display apparatus according to Embodiment 2 of the present invention.

FIG. 4 is a cross-sectional view showing a layout of major components of an image display apparatus according to Embodiment 3 of the present invention.

### DETAILED DESCRIPTION OF THE INVENTION

Based on the configuration as mentioned above, the image display apparatus of the present invention can be modified as follows.

The maximum cooling capacity of the cooling device depends upon the screen size. For example, the brightness of the screen is preferably 2000 cd/m² so as to ensure sufficient viewability in the outdoors. To achieve this brightness with the screen size of 50 inches (diagonal length) as a large and high-resolution image, the image display unit requires about 300 W of power consumption. Thus, it is desirable that the cooling device has a cooling capacity that can cancel 300 W of generated heat. In other words, when the screen size is 50 inches, the maximum cooling capacity of the cooling device is preferably 300 W or more. Moreover, in view of the influence of heat entering from the outside due to direct sunlight, the maximum cooling capacity of the cooling device is more preferably 500 W or more.

When the screen size doubles, the necessary light amount quadruples. Thus, when the screen size is 100 inches, the maximum cooling capacity of the cooling device is preferably 1200 W or more.

On the other hand, the brightness of 1000 cd/m² or more is undesirable in the nighttime since it is too bright. Thus, it is desirable to reduce the brightness of the image display apparatus to half or less of the brightness in the daytime and the power consumption of the image display unit also becomes half or less of that in the daytime. For this reason, the minimum cooling capacity at the time of operating the cooling device is desirably half or less of the maximum cooling capacity.

Further, it is preferable that the outer housing is divided into a heat-insulated section having an interior with a sealed structure and a non-heat-insulated section that is not sealed, the heat insulator is placed on interior walls of the heat-insulated section, the heat-insulated section is provided with the window, and the image display unit is placed in the heat-insulated section.

Further, a heat radiator unit of the cooling device may be placed in the non-heat-insulated section and a heat absorber unit of the cooling device may be placed in the heat-insulated section.

The cooling device may include a compressor, a condenser, an evaporator and a first cooling fan

Although a variety of means have been in the actual use to achieve cooling devices, a configuration utilizing the principle of the refrigeration cycle involving such a phase change enables the maximum cooling capacity sufficient for canceling an amount of heat generated by the image display unit to be ensured and to cool a desired area in the image display apparatus properly to the same extent as the ambient temperature.

In this configuration, it is preferable that the cooling device includes a second cooling fan and a heat exchanger using heat conduction.

Unlike the first cooling device that utilizes the principle of the refrigeration cycle, the second cooling device is not a cooling device capable of cooling the temperature to be lower than the ambient temperature but a heat exchanger that performs cooling by radiating heat. A plate fin, heat pipe or radiator can be used for the heat exchanger. The second cooling fan can be used in combination with the first cooling fan to enhance the efficiency of the heat exchanger.

In this way, by providing the apparatus with the two cooling devices, it is possible to achieve more appropriate cooling in accordance with the ambient temperature and the internal power consumption. When a large cooling capacity is not needed, the second cooling device is operated solely so that it is possible to cool the interior of the apparatus effectively with small power consumption.

Further, the cooling capacity of the cooling device may be adjusted on the basis of the rotational speed of a motor of the compressor. As a result of such a configuration, for example, the cooling capacity of the image display device can be controlled in an efficient manner by properly controlling the rotational speed of the motor of the compressor using an inverter circuit.

Further, the cooling capacity of the cooling device may be adjusted on the basis of the rotational speed of a motor of the first cooling fan or the second cooling fan. As a result of such a configuration, the cooling capacity can be adjusted easily by simply changing the rotational speed of the motor of either cooling fan.

Further, the cooling capacity of the cooling device may be adjusted by switching flow paths of air in the cooling device. As a result of such a configuration, the cooling capacity of the cooling device can be adjusted easily by switching the paths of cool air and hot air in the image display apparatus.

Further, the cooling capacity of the cooling device may be adjusted on the basis of the power consumption of the image display unit. Since an internal heat output changes in accordance with the power consumption of the image display unit, the cooling capacity is preferably adjusted on the basis of the power consumption of the image display unit.

It is preferable that the image display apparatus further includes a first temperature sensor and a second temperature sensor in the outer housing. The first temperature sensor detects a temperature corresponding to the ambient temperature of the outer housing, the second temperature sensor detects a temperature corresponding to a portion of the image display unit, and the cooling capacity of the cooling device is adjusted on the basis of temperature information detected by the first and the second temperature sensors.

As a result of such a configuration, both the ambient temperature in which the image display apparatus is placed and the temperature inside the image display apparatus can be detected at the same time. In other words, since it is possible to carry out control on the basis of information on both external environmental load and load of internally generated heat, the cooling capacity can be adjusted properly.

Further, the image display unit may be a projection type display unit that displays an image by modulating light from a light source to form the optical image and projecting the optical image, and the optical image may be projected to the outside through the window.

Further, the image display unit may be a projection type display unit, the outer housing further may house a transmissive screen and the optical image may be projected from the image display unit, and the transmissive screen may be placed so that the projected optical image is observable from the outside.

As a result of such a configuration, the image display apparatus with a projector system in which the image display unit is apart from the screen is achieved.

Thus, the influence of direct sunlight can be reduced as compared with a direct-view-type display.

Hereinafter, embodiments of the present invention will be described with reference to the drawings.

### Embodiment 1

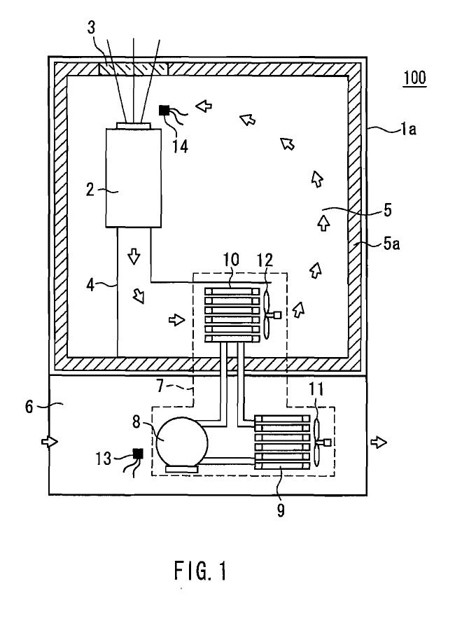

FIG. 1 is a cross-sectional view showing a layout of major components of an image display apparatus 100 (hereinafter referred to as “the apparatus 100”) according to Embodiment 1 of the present invention. This embodiment is directed to a basic configuration of the image display apparatus of the present invention. In the apparatus 100, the unit of a projector 2 of a projection type image display device is placed in an outer housing 1a as an image display unit. The projector 2 is configured to display an image by modulating light from a light source to form an optical image and projecting the optical image. By projecting the image light outputted from the projector 2 through a window 3, the image can be displayed on a large screen. An information processor (not shown) such as a personal computer is connected to the projector 2 so as to store information necessary for performing an information-supply service or allow information to be obtained externally through a communication line.

One of the configurational features of the apparatus 100 is that the image display unit is placed in a heat-insulated area of the outer housing where a heat insulator is disposed and a cooling device for cooling the heat-insulated area is provided. Hereinafter, major components of the apparatus 100 and their functions will be described.

The outer housing 1a is divided into a first heat-insulated section 5 having an interior with a sealed structure and a non-heat-insulated section 6 that is not sealed. The first heat-insulated section 5 is formed in a box shape and a first heat insulator 5a is disposed on the interior walls of the first heat-insulated section 5. The window 3 is built into the heat insulator 5a, and the projector 2 is placed inside the first heat-insulated section 5.

The first heat-insulated section 5 is designed so that the projector 2 is cooled efficiently by cold air supplied by a first cooling device 7. The first cooling device 7 is composed of a compressor 8, a condenser 9, an evaporator 10, a first cooling fan 11 and a second cooling fan 12. The compressor 8, the condenser 9 and the first cooling fan 11 are placed in the non-heat-insulated section 6 and the evaporator 10 and the second cooling fan 12 are placed in the first heat-insulated section 5. An exhaust portion of the projector 2 and the evaporator 10 are connected to each other through an exhaust duct 4.

The first heat insulator 5a is effective in maintaining the temperature inside the heat-insulated section 5 to the same as or lower than the outside air temperature detected by a first temperature sensor 13. The temperature of the surface of the outer housing 1a becomes significantly higher than the outside air temperature when the apparatus 100 is exposed to direct sunlight particularly in the outdoors. However, by providing the first heat insulator 5a, an influx of heat from the outside can be suppressed effectively.

Similarly, in order to suppress an influx of heat into the first heat-insulated section 5, the window 3 desirably is made of a material with a low heat conductivity. More preferably, the window 3 is formed not of a single-layered plate but of a multi-layered plate having a smaller heat conductively.

The window 3 is placed on an upper portion and image light is projected upwardly by the projector 2. However, the direction in which the image light is projected is not limited to the upward direction, and the image light may be projected horizontally or downwardly. Further, the image display unit is not limited to a projector, and the same effects of the present invention can be achieved even when a liquid crystal display or plasma display is used for the image display unit. When using a liquid crystal display or plasma display, the apparatus is configured so that an image displayed by either display is observed through the window 3. For this reason, the liquid crystal display or plasma display is placed to face the window 3.

Next, a flow of air in the first heat-insulated section 5 will be described. Warm exhaust air containing heat generated by the projector 2 passes through the exhaust duct 4 and flows into the evaporator 10. The air cooled as a result of passing through the evaporator 10 is exhausted by the second cooling fan 12 and circulates in the first heat-insulated section 5. Then, the air flows into the projector 2 again through an air intake of the projector 2. In this way, a flow of air in the first heat-insulated section 5 including taking air into and exhausting air from the projector 2 has an internal circulation structure cut off from the outside. By adopting such a configuration, it is possible to provide an image display apparatus less susceptible to the influences of wind and rain, humidity, dust and the like.

At the non-heat-insulated section 6, air is taken in from the outside of the outer housing 1a. The air passes through the interior of the non-heat-insulated section 6 to cause heat radiation inside the first cooling device 7, and is exhausted from the outer housing 1a again by the first cooling fan 11.

A circulation cycle of the air conditioner is as follows. First, refrigerant gas is compressed by the compressor 8 to a high temperate state and is sent to the condenser (aluminum fins) 9. The refrigerant gas is cooled in the condenser 9 by the first cooling fan 11 and is liquefied, and then is sent to the evaporator 10. In the evaporator 10, the liquefied gas evaporates while taking the heat of vaporization away from the surroundings to cool the aluminum fins.

Temperature detection is carried out by the first temperature sensor 13 placed in the non-heat-insulated section 6 and a second temperature sensor 14 placed in the first heat-insulated section 5. Further, a power supply unit and a control unit (both of which are not shown) are placed in the outer housing 1a, so that cooling is controlled on the basis of values detected by the two temperature sensors 13, 14.

As described above, the apparatus 100 includes the first cooling device 7 as an air conditioner based on the refrigeration cycle. The rotational speed of the motor of the compressor 8 and the rotational speed of the motors of the first and second fans 11, 12 are variable and are controlled on the basis of the first temperature sensor 13, the second temperature sensor 14 and the power consumption of the projector 2 so as to achieve an appropriate cooling capacity.

When the temperature of the first heat-insulated section 5 as the space in which the projector 2 is placed becomes significantly lower than the ambient temperature of the outer housing 1a, condensation may occur. For this reason, it is preferable that the temperature of the heat-insulated section 5 does not become lower than the ambient temperature by 5° C. or more.

The problem that may arise when the inside of the first heat-insulated section 5 is cooled excessively is as described above. Hereinafter, other problems that may occur when the cooling capacity of the first cooling device 7 is not variable will be described.

Cooling in an image display apparatus is performed to cool an object having a large heat-generating source inside. Air conditioning of rooms in a building is one of the typical examples in which such cooling is performed. In comparison to cooling of a building space, the first heat-insulated section 5 of this image display apparatus has a large heat output for its space volume.

When the cooling device has a fixed cooling capacity, temperature control is to be carried out by simply switching the cooling device between ON and OFF. However, since the thermal capacity of the object to be cooled in the image display apparatus is small, if the cooling device capable of canceling heat generated by the image display unit to a sufficient degree is operated in simple a binary fashion of ON/OFF, the temperature inside the first heat-insulated section 5 increases sharply when the cooling device is turned OFF. In contrast, the temperature inside the first heat-insulated section 5 drops sharply when the cooling device is turned ON.

In such a case, the interval between ON/OFF of the cooling device becomes short when the temperature inside the first heat-insulated section 5 is controlled to be maintained at a constant temperature as possible. Generally, it is known that the life of a motor used in a condenser becomes shorter as the number of instances where the motor is turned ON/OFF increases. Therefore, to increase the life of the cooling device, it is desirable to reduce the number of instances where the cooling device is turned ON/OFF as possible.

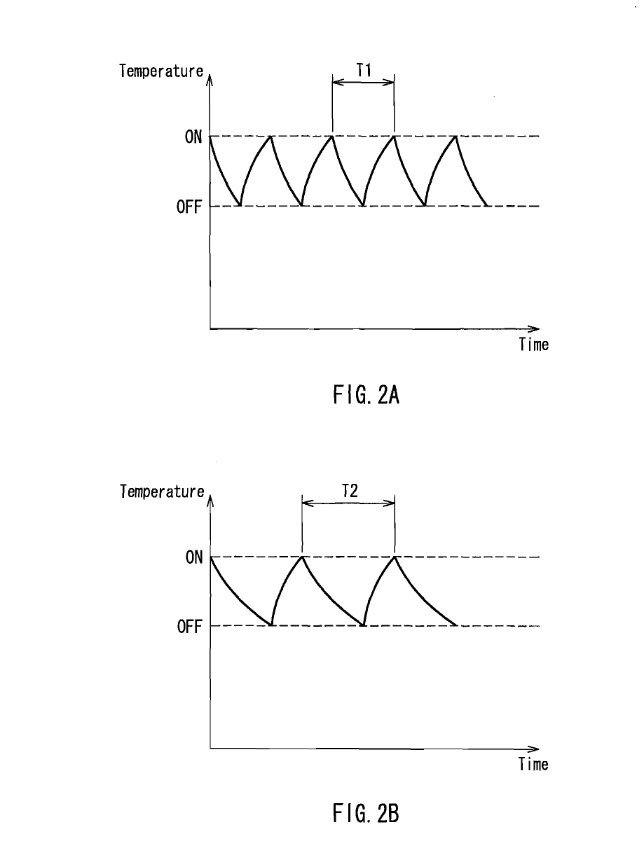

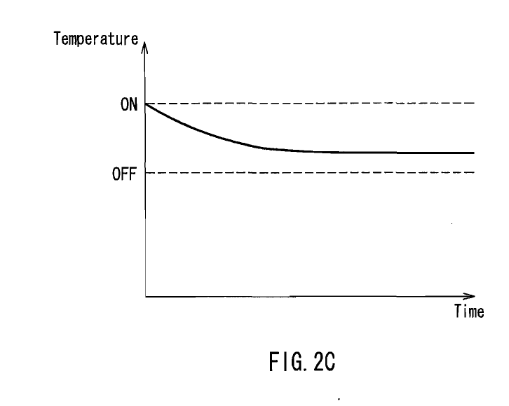

FIGS. 2A to 2C each schematically show the relationship between the capacity of the first cooling device 7 and values measured by the second temperature sensor 14. The cooling capacity is the largest in FIG. 2A, followed by the capacities in FIG. 2B and FIG. 2C. The horizontal axis indicates the operating time and the vertical axis indicates the temperature. The OFF temperature indicates the temperature at which the cooling device is turned off and the ON temperature indicates the temperature at which the cooling device is turned on. Appropriate hysteresis is set between the ON and OFF temperatures to carry out stable control.

Since the cooling capacity in FIG. 2A is too large, the temperature is cooled to the OFF temperature within a short time after the cooling device is turned on. Although the cooling device is turned off when the temperature is cooled to the OFF temperature, this time, the temperature rises to the ON temperature within a short time due to the heat generated by the image display unit. Consequently, the cooling device is turned ON/OFF repeatedly at intervals T1. The cooling capacity in FIG. 2B is set to be smaller than the cooling capacity in FIG. 2A, so that the time required to cool the temperature to the OFF temperature is longer than that in FIG. 2A. Thus, the relationship between the ON/OFF intervals becomes T1<T2. Even still, the cooling device is turned ON/OFF repeatedly at regular intervals.

The cooling capacity in FIG. 2C is set to be further smaller so that the temperature does not reach the OFF temperature even if the cooling device is operated continuously. By adjusting the cooling capacity in this way, values detected by the temperature sensor in a steady state saturate between the ON and OFF temperatures. Thus, the life of the cooling device can be increased by reducing the number of instances that the motor is turned ON/OFF.

Also because of the reasons as described above, the cooling device 7 preferably has a variable cooling capacity. For example, the rotational speed of the motor in the compressor 8 may be made variable by using an inverter circuit and the rotational speed of the first cooling fan and the second cooling fan also may be made variable.

### Embodiment 2

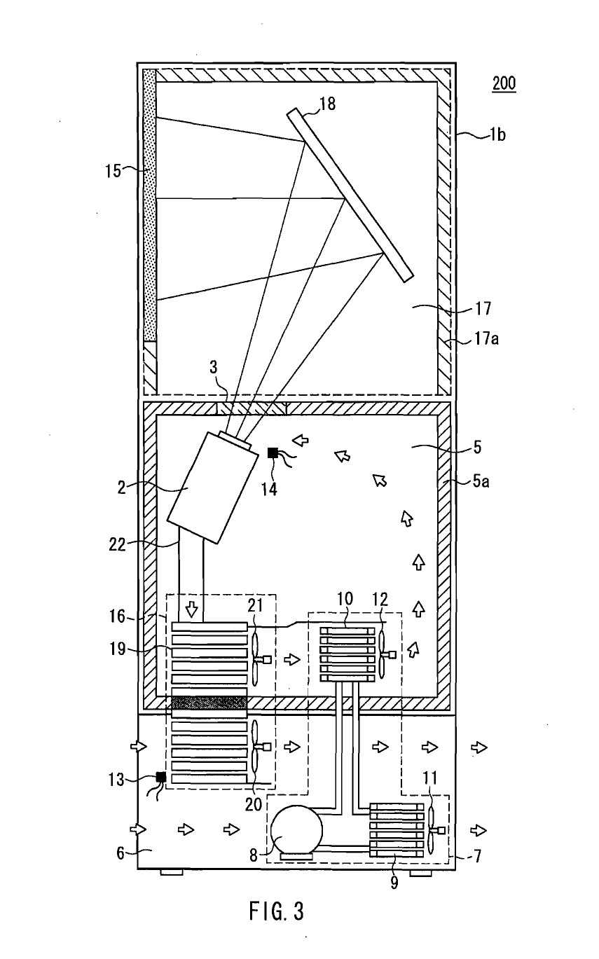

FIG. 3 is a cross-sectional view showing a layout of major components of an image display apparatus 200 (hereinafter referred to as “the apparatus 200”) according to Embodiment 2 of the present invention. This embodiment is directed to an application example of the image display apparatus according to Embodiment 1. In the following description, the same components as in Embodiment 1 each are denoted by the same reference numeral as shown in FIG. 1 and the description thereof will not be partially repeated.

The apparatus 200 is different from the apparatus according to Embodiment 1 in that a transmissive screen 15 is incorporated in an outer housing 1b and a second cooling device 16 is adopted in addition to the first cooling device 7.

In this embodiment, the outer housing 1b is divided into the first heat-insulated section 5 and a second heat-insulated section 17 each having an interior with a sealed structure and the non-heat-insulated section 6 that is not sealed. The transmissive screen 15 is placed on one of the surfaces surrounding the second heat-insulated section 17 and a second heat insulator 17a is placed on the remaining surfaces. Further, a mirror 18 is placed inside the second heat-insulated section 17. The first heat-insulated section 5 and the second heat-insulated section 17 are separated from each other by the heat insulator 5a and the window 3.

The second cooling device 16 as well as the first cooling device 7 are placed in the first heat-insulated section 5 and the non-heat-insulated section 6. The second cooling device 16 is composed of a heat exchanger 19, a third cooling fan 20 and a fourth cooling fan 21. Although the heat exchanger 19 extends between the first heat-insulated section 5 and the non-heat-insulated section 6, there is no flow of air between the first heat-insulated section 5 and the non-heat-insulated section 6 and only the flow of heat takes place. In other words, the portion of the heat exchanger 19 positioned in the first heat-insulated section 5 is a heat absorber portion and the portion positioned in the non-heat-insulated section 6 is a heat radiator portion.

Heat of the exhaust air from the projector 2 is adsorbed by the heat exchanger 19 and then the exhaust air passes through the fourth cooling fan 21 and flows into the evaporator 10. The subsequent flow of air is the same as in Embodiment 1. Also in this embodiment, the air path in the heat-insulated section 5 is cut off from the outside and the air circulates within the sealed space.

In addition to components of the first cooling device 7, the heat radiator portion of the heat exchanger 19 and the third cooling fan 20 as components of the second cooling device 16 are placed in the non-heat-insulated section 6. Air taken into the outer housing 1B from the outside passes through the inside of the non-heat-insulated section 6 to radiate heat of the heat exchanger 19, and then is exhausted from the outer housing 1B again by the third cooling fan 20.

As in this embodiment, by providing the apparatus with the two cooling devices, it is possible to achieve further appropriate cooling effects in accordance with the ambient temperature and the internal power consumption.

In some cases, the first cooling device 7, which is based on the refrigeration cycle, may not be able to operate with a high degree of reliability in a low ambient temperature state. In such cases, by operating the second cooling device 16 as a primary cooling device, it is possible to cool the heat-insulated section 5 effectively. Further, also when a large cooling capacity is not necessary, it is possible to achieve desired cooling by solely operating the first cooling device 7.

As a path for letting exhaust air from the projector 2 pass through the two cooling devices 7, 16, it is preferable to let the air pass through the second cooling device 16 first and the first cooling device 7 next. Since the second cooling device 16 is a heat exchanger utilizing a temperature difference from the ambient temperature, it is more efficient when there is a larger temperature difference between the heat absorber portion and the heat radiator portion. Therefore, it is appropriate to have a configuration that allows the temperature of the heat absorber portion to become as high as possible. For this reason, it is preferable to let the exhaust air from the projector flow into the second cooling device 16 first.

Since the fans 20, 21 are the only major components that consume power, the second cooling device 16 is an efficient cooling device with low power consumption. In this embodiment, a total cooling capacity of the cooling devices is adjusted so that the temperature of the air intake portion of the projector 2 in the heat-insulated section 5 is always maintained at a certain temperature or less, more specifically, the temperature of the air intake portion of the projector 2 is 40° C. or less.

As an example, the second cooling device 16 is operated as a primary cooling device in a range where no trouble occurs even when the temperature inside the heat-insulated portion 5 is about 15° C. higher than the ambient temperature. When the ambient temperature detected by the first temperature sensor 13 is about 20° C. or less, the second cooling device 16 is operated solely. When the ambient temperature is higher than 20° C., the second cooling device 16 is operated in combination with the first cooling device 7 and the cooling capacity of the first cooling device 7 is controlled to be increased with a rise in the ambient temperature. In this way, by adjusting the total cooling capacity appropriately including turning the two cooling devices ON/OFF, the temperature of the air intake portion of the projector 2 can be maintained easily at 40° C. or less at all usual ambient temperatures.

### Embodiment 3

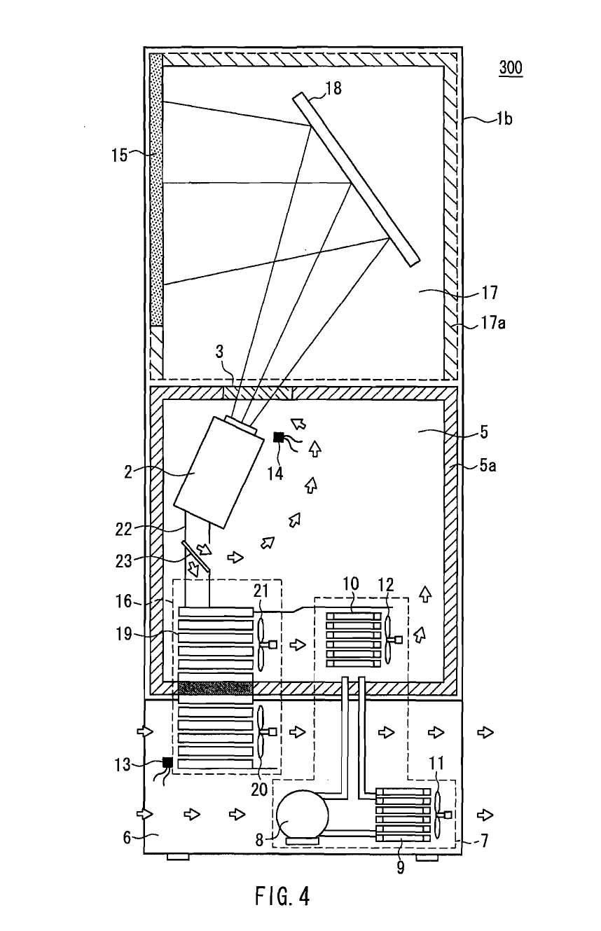

FIG. 4 is a cross-sectional view showing a layout of major components of an image display apparatus 300 (hereinafter referred to as “the apparatus 300”) according to Embodiment 3 of the present invention. This embodiment is directed to an application example of the image display apparatus according to Embodiment 2. In the following description, the same components as in Embodiment 2 each are denoted by the same reference numeral as shown in FIG. 3 and the description thereof will not be partially repeated.

The apparatus 300 is different from the apparatus according to Embodiment 2 shown in FIG. 3 in that a path switching valve 23 is placed in the exhaust duct 22 from the projector 2.

When the switching value 23 is open, exhaust air from the projector 2 does not flow directly into the cooling devices 16, 7 and is released into the space of the heat-insulated section 5. Thus, the temperature of air in the heat-insulated section 5 that flows into the cooling devices increases, the heat exchange efficiency drops and the capacities of the cooling devices drop as a result. On the other hand, when the switching valve 23 is closed, the path is the same as in FIG. 3. In this way, by opening/closing the switching valve 23, the capacities of the cooling devices can be adjusted.

Although the switching valve 23 having an opening/closing mechanism is used in this embodiment as an example of the path switching mechanism, any mechanism having the same function as the switching valve 23 may be used.

The invention may be embodied in other forms without departing from the spirit of essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An image display apparatus comprising:
an image display unit for forming an optical image; and
an outer housing for housing the image display unit, the outer housing including a window for displaying the optical image to outside,
wherein the image display apparatus includes, in the outer housing, a heat insulator placed so as to surround the image display unit and a cooling device for cooling inside the outer housing, and
the cooling device has a variable cooling capacity.

2. The image display apparatus according to claim 1, wherein the outer housing is divided into a heat-insulated section having an interior with a sealed structure and a non-heat-insulated section that is not sealed,
the heat insulator is placed on interior walls of the heat-insulated section, the heat-insulated section is provided with the window, and the image display unit is placed in the heat-insulated section.

3. The image display apparatus according to claim 2, wherein a heat radiator unit of the cooling device is placed in the non-heat-insulated section and a heat absorber unit of the cooling device is placed in the heat-insulated section.

4. The image display apparatus according to claim 1, wherein the cooling device includes a compressor, a condenser, an evaporator and a first cooling fan.

5. The image display apparatus according to claim 4, wherein the cooling device further includes a second cooling fan and a heat exchanger using heat conduction.

6. The image display apparatus according to claim 4, wherein the cooling capacity of the cooling device is adjusted on the basis of a rotational speed of a motor of the compressor.

7. The image display apparatus according to claim 4, wherein the cooling capacity of the cooling device is adjusted on the basis of a rotational speed of a motor of the first cooling fan.

8. The image display apparatus according to claim 5, wherein the cooling capacity of the cooling device is adjusted on the basis of a rotational speed of a motor of the second cooling fan.

9. The image display apparatus according to claim 5, wherein the cooling capacity of the cooling device is adjusted by switching flow paths of air in the cooling device.

10. The image display apparatus according to claim 1, wherein the cooling capacity of the cooling device is adjusted on the basis of power consumption of the image display unit.

11. The image display apparatus according to claim 1, further comprising a first temperature sensor and a second temperature sensor in the outer housing,
wherein the first temperature sensor detects a temperature corresponding to an ambient temperature of the outer housing, the second temperature sensor detects a temperature corresponding to a portion of the image display unit, and the cooling capacity of the cooling device is adjusted on the basis of temperature information detected by the first and the second temperature sensors.

12. The image display apparatus according to claim 1, wherein the image display unit is a projection type display unit that displays an image by modulating light from a light source to form the optical image and projecting the optical image, and
the optical image is projected to outside through the window.

13. The image display apparatus according to claim 1, wherein the image display unit is a projection type display unit,
the outer housing further houses a transmissive screen on which the optical image is projected from the image display unit, and
the transmissive screen is placed so that the projected optical image is observable from outside.
